(19) United States
(12) Patent Application Publication
(10) Pub. No.: US 2026/0230069 A1
(43) Pub. Date: Aug. 6, 2026

(54) ELECTRIC SWITCHING DEVICE

(71) Applicant: EATON INTELLIGENT POWER LIMITED, Dublin 4 (IE)

(72) Inventors: Kenan ASKAN, Vienna (AT); Nissim UVAIDOV, Klosterneuberg (AT)

(21) Appl. No.: 19/159,761

(22) PCT Filed: Mar. 11, 2024
(86) PCT No.: PCT/EP2024/025112

§ 371 Date: Aug. 26, 2025

(30) Foreign Application Priority Data
Mar. 16, 2023 (GB) 2303889.6

(51) Int. Cl. H03K 17/0814; H02H 3/20

(52) U.S. Cl. CPC H03K 17/08142; H02H 3/202; H03K 2217/0054

(57) ABSTRACT

Some embodiments relate to an electric switching device. Specifically, hybrid circuit breaker or a solid-state circuit breaker, including a first conductor path and a second conductor path-a first semiconductor circuit arrangement arranged in the first conductor path, the first semiconductor circuit arrangement at least a first semiconductor. At least a first varistor can be arranged in the first conductor path, the first varistor is connected in parallel to the first semiconductor circuit arrangement. An additional overvoltage protection device can be connected serial to the first varistor and parallel to the first semiconductor circuit arrangement, and that the additional overvoltage protection device is a gas discharge tube or an silicon thyristor for alternating current.

### CROSS-REFERENCE TO RELATED APPLICATIONS

This application is a national phase filing under 35 C.F.R. § 371 of and claims priority to PCT Patent Application No. PCT/EP2024/025112, filed on Mar. 11, 2024, which claims the benefit of British Application No. 2303889.6, filed on Mar. 16, 2023, the contents of which are hereby incorporated in their entireties by reference.

### FIELD OF THE DISCLOSURE

The presently disclosed subject matter relates to an electric switching device according to the generic part of claim 1.

### BACKGROUND TO THE DISCLOSURE

In state-of-the-art semiconductor and hybrid power switch topologies MOV (Metal Oxide Varistor) and TVS (Transient Voltage Suppressor) diodes are commonly used. In terms of circuitry, at least one varistor is connected in parallel with the semiconductor switching arrangement, which primarily performs the switch-off process. Due to the high clamping voltage of metal oxide varistors, transistors with a high breakdown voltage are required in the semiconductor switching arrangement. However, compared to transistors with a lower breakdown voltage, such transistors have a larger mass, a large volume and higher acquisition costs. The high voltages during the switch-off process and the constantly occurring high leakage currents lead to power loss and heating of such a switching arrangement. This heat must be dissipated. Heat dissipation and a cooling element are therefore required. This means that such a SSCB or HCB is heavy and has a large housing with a heat sink. The heat dissipation mounting limits the options for attaching of such a switch, since the cooling element usually does not function adequately in a narrow, in densely built-up location.

Combinations of a semiconductor circuit arrangement and a varistor arranged in parallel are known for protecting networks with a nominal voltage of 700 V DC, which nominal voltage can rise to 800 V DC. This means that the semiconductor arrangement shall be able to hold 800 V continues when it is in off-state, meaning conducting no current from source to load. In this case, the varistor should be able to hold the sustained 800 V without significant leakage current flowing through. In applications, the varistor leakage current should not normally exceed 1 mA at 85° C. ambient temperature of the varistor. This would require a varistor that can continue to hold 800 V at less than 1 mA leakage current at 85° C. ambient temperature. The higher the continuous operating voltage, the higher the clamping voltage at high pulse current. For SSCB and HCB applications, the cut-off current can be up to several kA. During the shutdown process of the semiconductor device, the peak voltage of the varistor reaches over 2500 V. Therefore, the semiconductor switches used in the semiconductor device must have a breakdown voltage of more than 2500 V. Usually IGBTs are used for this application. In this case, an IGBT with 3300 V turn-off voltage is required, resulting in a very bulky and expensive solution. An alternative solution would be to use transient voltage suppression (TVS) diodes instead of metal oxide varistors (MOV), since TVS have lower clamping and leakage currents. However, during the shutdown process, the energy stored in the line inductance and leakage inductance must be dissipated by the TVS diode, which has a much lower energy dissipation capability than the MOV. Several TVS diodes could be connected in parallel, but this is also an expensive and bulky solution. Another option is to connect a galvanic isolation relay in series with the semiconductor device. Once the semiconductor switch is in the off state and the current flow is approximately zero amps, the galvanic separation relay is opened to prevent any operating voltage from continuing to appear at the surge protection device or the semiconductor device. The galvanic isolating relay must therefore be able to open its contacts even in the event of leakage currents in such a circuit configuration. However, the service life of such galvanic isolating relays is limited due to the load during such operation.

It is an object of the presently disclosed subject matter to overcome the drawbacks of the state of the art by providing an electric switching device with a compact volume, a lower mass, a low power loss and a high reliability in operation.

According to the presently disclosed subject matter, the aforementioned object is solved by the features of claim 1.

The circuit arrangement for protection against overvoltage has been improved, enabling the use of semiconductor switches with lower breakdown voltage. In the circuit arrangement for protection against overvoltage, too, a varistor with a lower clamping voltage can now be used-for the same mains voltage or protective capacitance. Such a circuit arrangement for protection against overvoltage has significantly lower leakage currents. Therefore, the power dissipation of such a varistor and its self-heating at high continuous operating voltage is avoided while the semiconductor arrangement is in the off-state.

By placing a gas discharge tube (GDT) or silicon thyristor for alternating current (SYDAC) in series with the varistor, the circuit arrangement for protection against overvoltage is able to keep the leakage current below 1 mA while the semiconductor switch is in the off state at full source voltage. This allows semiconductors or transistors with a lower breakdown voltage to be used for the switching operation. Such transistors have lower mass and smaller volume. In addition, these transistors also have lower acquisition costs.

Such an electrical switching device has a more compact housing and does not require a galvanic separation switch. In normal switching on and off operations, the use of a galvanic separation switch is not part of the switching operation. It also has a low mass and high operability. Therefore, much less space is required for the arrangement of such an electrical switching device, which also does not have excessive heat dissipation.

The dependent claims describe further preferred embodiments of the presently disclosed subject matter.

The presently disclosed subject matter is described with reference to the drawings. The drawings show only exemplary embodiments of the presently disclosed subject matter.

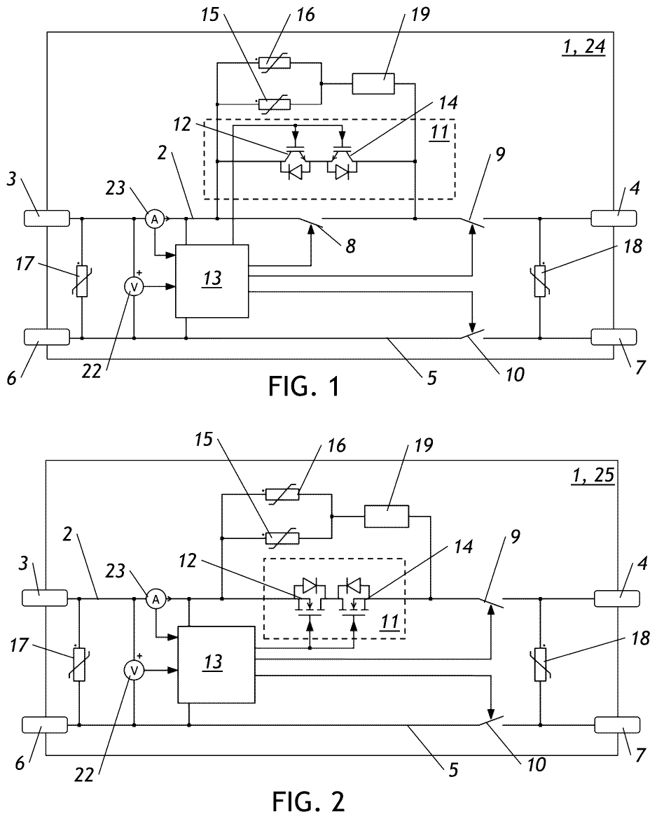

FIG. 1 illustrates a first preferred embodiment of an electric switching device; and

FIG. 2 illustrates a second preferred embodiment of an electric switching device.

FIGS. 1 and 2 illustrate preferred embodiments of an electric switching device 1, especially a hybrid circuit breaker 24 or a solid-state circuit breaker 25, for a predefined power supply voltage comprising:
a first conductor path 2 and a second conductor path 5,
a first semiconductor circuit arrangement 11 arranged in the first conductor path 2, the first semiconductor circuit arrangement 11 comprising at least a first semiconductor 12,
at least a first varistor 15 arranged in the first conductor path 2, the first varistor 15 is connected in parallel to the first semiconductor circuit arrangement 11,
a first control and driver unit 13 configured to drive the first semiconductor circuit arrangement 11 with control signals,
an additional over-voltage protection device 19 connected serial to the first varistor 15 and parallel to the first semiconductor circuit arrangement 11, the additional over-voltage protection device 19 is a gas discharge tube or a silicon thyristor for alternating current.

The circuit arrangement for protection against overvoltage has been improved, enabling the use of semiconductor switches 12, 14 with lower breakdown voltage. The circuit arrangement for protection against overvoltage comprise the varistor 15, 16 and the additional over-voltage protection device 19. In the circuit arrangement for protection against overvoltage, too, a varistor 15, 16 with a lower clamping voltage can now be used-for the same mains voltage or protective capacitance. Such a circuit arrangement for protection against overvoltage has significantly lower leakage currents. Therefore, the power dissipation of such a varistor 15, 16 and its self-heating at high continuous operating voltage is avoided while the semiconductor circuit arrangement 11 is in the off-state.

By placing a gas discharge tube (GDT) or a silicon thyristor for alternating current (SYDAC) in series with the varistor 15, 16, the circuit arrangement for protection against overvoltage is able to keep the leakage current below 1 mA while the semiconductor 12, 14 is in the off state at full source voltage. This allows semiconductors 12, 14 or transistors with a lower breakdown voltage to be used for the switching operation. Such semiconductors 12, 14 have lower mass and smaller volume. In addition, these semiconductors 12, 14 also have lower acquisition costs. Such an electrical switching device 1 has a more compact housing and does not require a galvanic separation switch 9, 10. In normal switching on and off operations, the use of a galvanic separation switch 9, 10 is not part of the switching operation. It also has a low mass and high operability. Therefore, much less space is required for the arrangement of such an electrical switching device 1, which also does not have excessive heat dissipation.

The present device is an electric switching device 1 for protecting in a low voltage arrangement. The power supply voltage is in the range up to 1000V AC and/or 1500V DC, especially up to 900 V AC and/or 1400 V DC, preferably about 700 V DC. In known electric switching devices 1, semiconductor switches with a breakdown voltage of approximately 3300 V are required to protect a network with a rated voltage of 700 V. With the presently disclosed subject matter, semiconductor switches 12, 14 with a breakdown voltage between 1200 V and 1700 V can be used for operation with a nominal voltage of 700 V.

Preferably the electric switching device 1 can be embodied as circuit breaker or as part of a circuit breaker. According to the first preferred embodiment-as shown in FIG. 1—the electric switching device 1 is embodied as hybrid circuit breaker 24 or HCB. According to the second preferred embodiment-as shown in FIG. 2—the electric switching device 1 is embodied as solid-state circuit breaker 25 or SSCB.

The electric switching device 1 has at least a first conductor path 2 and a second conductor path 5. Another name of the first conductor path 2 is outer conductor path. Another name of the second conductor path 5 is neutral conductor path 5 in alternative current. The first conductor path 2 runs through the electric switching device 1 from a first power supply connection 3 to a first load connection 4. The second conductor path 5 runs through the electric switching device 1 from a second power supply connection 6 to a second load connection 7. The respective connections 3, 4, 6, 7 are preferably designed as screw connection terminals and/or plug-in terminals. The respective connections 3, 4, 6, 7 are preferably arranged at the electric switching device 1 in a manner allowing access from the outside. This means that if the electric switching device 1 is a part of another device, especially a circuit breaker, preferably a hybrid circuit breaker 24 or a solid-state circuit breaker 25, the respective connections 3, 4, 6, 7 are part of the other device. In FIGS. 1 and 2 the connections 3, 4, 6, 7 are part of the electric switching device 1 embodied as hybrid circuit breaker 24 or as solid-state circuit breaker 25.

The electric switching device 1 preferably has-at least in sections-a housing of insulating material. Preferably all components of the electric switching device 1 are arranged in one housing. If the electric switching device 1 is part of another device, the housing of this device is the housing of the electric switching device 1. The electric switching device 1 comprises a first semiconductor circuit arrangement 11 arranged in the first conductor path 2. The first semiconductor circuit arrangement 11 comprises at least a first semiconductor 12. Preferably, the first semiconductor circuit arrangement 11 further comprises a second semiconductor 14.

Preferably, the first and/or the second semiconductor 12, 14 is embodied as IGBT or as enhancement-FET, especially as MOSFET.

In case the electric switching device 1 is embodied as HCB the first and/or the second semiconductor 12, 14 is preferably embodied as IGBT. If the first and/or the second semiconductor 12, 14 are embodied as IGBT, a diode is arranged parallel to the first semiconductor 12 and another diode is arranged parallel to the second semiconductor 14. According to a first preferred embodiment of the presently disclosed subject matter, the first and/or the second semiconductor 12, 14 is embodied as IGBT, and the collector-to-emitter voltage of the IGBT is in the range 190%-260%, preferably 210%-250%, of the power supply voltage. If the power supply is a DC-grid and the power supply voltage is in the range of 700 V DC with continues operation voltage up to 800 V DC, collector-to-emitter voltage respectively the breakdown voltage of the transistor(s) of the first semiconductor circuit 11 is in about 1700 V.

In case the electric switching device 1 is embodied as SSCB the first and/or the second semiconductor 12, 14 is preferably embodied as MOSFET. If the first and/or the second semiconductor 12, 14 are embodied as MOSFET, the device has its natural monolith body diode. According to a second alternative preferred embodiment of the presently disclosed subject matter, the first and/or the second semiconductor 12, 14 is embodied as MOSFET, and the drain-to-source voltage of the MOSFET is in the range of 190%-260%, preferably 210%-250%, of the power supply voltage.

The electric switching device 1 comprises a first control and driver unit 13. The first control and driver unit 13 is at least configured to drive the first semiconductor circuit arrangement 11. The first control and driver unit 13 drives at least the first semiconductor 12 with control signals. In a preferred embodiment of the electric switching device 1, the first control and driver unit 13 also drives the second semiconductor 14. The first control and driver unit 13 uses the energy of the power supply to which the electric switching device 1 is connected. For this electric energy supply, the first control and driver unit 13 is connected to the first conductor path 2 and the second conductor path 5. The first control and driver unit 13 is voltage dependent, and requires a supply voltage to operate. Typically, the first control and driver unit 13 require a source voltage of at least 50-70 V. Alternatively to the direct connection of the first control and driver unit 13 with the first conductor path 2 and the second conductor path 5 the electric switching device 1 can comprise a selective power supply, which is not shown in FIGS. 1 and 2.

In these embodiments the power supply delivers the required supply voltage above 50-70 V to operate the first control and driver unit 13.

The electric switching device 1 comprises a first galvanic separation switch 9, and preferably a second galvanic separation switch 10. The first galvanic separation switch 9 is arranged in the first conductor path 2, between the first semiconductor circuit arrangement 11 and the first load connection 4. The preferred second galvanic separation switch 10 is arranged in the second conductor path 5, between the power supply connection of the first control and driver unit 13 and the second load connection 7. The first and the second galvanic separation switches 9, 10 are controlled by the first control and driver unit 13.

According to the preferred embodiments, the electric switching device 1 comprises a voltage detector 22. The voltage detector 22 is connected with the first conductor path 2 and the second conductor path 5. These connections are arranged near the first and the second power supply connections 3, 6.

According to the preferred embodiments, the electric switching device 1 also comprises a current measuring device 23. The current measuring device 23 is arranged in the first conductor path 2, especially between the first power supply connection 3 and the first semiconductor circuit arrangement 11.

According to the second preferred embodiment as shown in FIG. 2 the electric switching device 1 is embodied as solid-state switching device, especially as solid-state circuit breaker 25, without any mechanical switch in the first conductor path 2, which would be parallel to the first semiconductor circuit arrangement 11.

According to the first preferred embodiment as shown in FIG. 1 the electric switching device 1 is embodied as hybrid circuit switching device, especially as hybrid circuit breaker 24. In the embodiment as hybrid switching device the electric switching device 1 further comprises a mechanical bypass switch 8 which is arranged in the first conductor path 2. The mechanical bypass switch 8 is connected parallel to the first semiconductor circuit arrangement 11. Furthermore, the mechanical bypass switch 8 is driven by the first control and driver unit 13. In an alternative embodiment, the electric switching device 1 comprises an individual relay driver, and the mechanical bypass switch 8 is connected with the relay driver.

The electric switching device 1 comprises a first varistor 15, a voltage-dependent resistor, arranged in the first conductor path 2. The first varistor 15 is connected in parallel to the first semiconductor circuit arrangement 11. In the first preferred embodiment, the first varistor 15 is also connected in parallel to the mechanical bypass switch 8. Preferably the first varistor 15 has a maximum clamping voltage of 115% to 125%, preferably of 120%, of the power supply voltage.

Preferably, the electric switching device 1 comprises a second varistor 16, the second varistor 16 is connected in parallel to the first varistor 15. The second varistor 16 would be the same type of varistor as the first varistor 15.

If the power supply is a DC-grid and the power supply voltage is in the range of 700 V DC with continues operation up to 800 V DC, the maximum clamping voltage V_{c,max} of the first varistor 15 and/or the second the second varistor 16 would be in the range of 820 V to 860V, especially about 840 V at 25° C. ambient temperature.

According to the first and the second preferred embodiment as shown in FIGS. 1 and 2, the electric switching device 1 further comprises a third and a fourth varistor 17, 18. The third varistor 17 is arranged near the first and the second power supply connections 3, 6 and connected with the first and the second conductor path 2, 5. Especially the third varistor 17 is arranged between the first and the second power supply connection 3, 6 and the power connections of the first control and driver unit 13. The fourth varistor 18 is arranged near the first and the second load connections 4, 7 and connected with the first and the second conductor path 2, 5. Especially the fourth varistor 18 is arranged between the first and the second load connection 4, 7 and the first and the second galvanic separation switch 9, 10.

The clamping voltage of the third and the fourth varistors 17, 18 is higher than the clamping voltage of the first and the second varistors 15, 16. The third and the fourth varistors 17 and 18 are used to protect the input and output of electric switching device 1 against pulse voltages coming from outside, e.g. 8 kV 1.2/50 μs pulse voltage. The third and the fourth varistors 17 and 18 are selected to operate under maximum continuous voltage with a leakage current of less than 1 mA. Therefore, the third and the fourth varistors 17, 18 have a very high clamping voltage.

According to the preferred embodiments, the first varistor 15 and/or the second varistor 16 and/or the third varistor 17 and/or the fourth varistor 18 is a metal-oxide-varistor or MOV.

The electric switching device 1 comprises an additional over-voltage protection device 19. This additional over-voltage protection device 19 is a gas discharge tube or a silicon thyristor for alternating current. An abbreviation for “gas discharge tube” is GDT. An abbreviation for “silicon thyristor for alternating current” is SYDAC. Another name for “silicon thyristor for alternating current” would be “overvoltage protection thyristor”. The electric switching device 1 comprises at least one, preferably only one, of these devices at this point of the circuit arrangement.

The gas discharge tube or the silicon thyristor for alternating current is connected serial to the first varistor 15 and parallel to the first semiconductor arrangement 11. If the electric switching device 1 comprises a second varistor 16, the gas discharge tube or the silicon thyristor for alternating current is also connected serial to the second varistor 16. In the first preferred embodiment as shown in FIG. 1, the first varistor 15 and the gas discharge tube or the silicon thyristor for alternating current are further connected in parallel to the mechanical bypass switch 8.

By an embodiment of the additional over-voltage protection device 19 as gas discharge tube, the gas discharge tube has preferably a sparkover voltage of 45% 55% of the power supply voltage.

If the power supply is a DC-grid and the power supply voltage is in the range of 700 V DC with peaks up to 800 V DC, and the additional over-voltage protection device 19 is a gas discharge tube, the gas discharge tube preferably has a sparkover voltage in the range of 340 V to 370 V, especially about 350 V.

By an embodiment of the additional over-voltage protection device 19 as silicon thyristor for alternating current, the silicon thyristor for alternating current has preferably a blocking voltage of 45%-55% of the power supply voltage.

If the power supply is a DC-grid and the power supply voltage is in the range of 700 V DC with maximum continues up to 800 V DC, and the additional over-voltage protection device 19 is a silicon thyristor for alternating current, the silicon thyristor for alternating current preferably has a blocking voltage in the range of 320 V to 400 V, especially about 350 V.

While the presently disclosed subject matter has been particularly shown and described with reference to exemplary embodiments thereof, it will be understood by those skilled in the art that various changes in form and details may be made therein without departing from the spirit and scope of the presently disclosed subject matter as defined by the appended claims. The exemplary embodiments should be considered as descriptive only and not for purposes of limitation. Therefore, the scope of the presently disclosed subject matter is not defined by the detailed description but by the appended claims.

Hereinafter are principles for understanding and interpreting the actual disclosure.

Features are usually introduced with an indefinite article “one, a, an”. Unless otherwise stated in the context, therefore, “one, a, an” is not to be understood as a numeral.

The conjunction “or” has to be interpreted as inclusive and not as exclusive, unless the context dictates otherwise. “A or B” also includes “A and B”, where “A” and “B” represent random features.

By means of an ordering number word, for example “first”, “second” or “third”, in particular a feature X or an object Y is distinguished in several embodiments, unless otherwise defined by the disclosure of the presently disclosed subject matter. In particular, a feature X or object Y with an ordering number word in a claim does not mean that an embodiment of the presently disclosed subject matter covered by this claim must have a further feature X or another object Y.

An “essentially” in conjunction with a numerical value includes a tolerance of ±10% around the given numerical value, unless the context dictates otherwise.

For ranges of values, the endpoints are included, unless the context dictates otherwise.

1. Electric switching device, especially a hybrid circuit breaker or a solid-state circuit breaker, for a predefined power supply voltage comprising:
a first conductor path and a second conductor path,
a first semiconductor circuit arrangement arranged in the first conductor path, the first semiconductor circuit arrangement including at least a first semiconductor,
at least a first varistor arranged in the first conductor path, the first varistor is connected in parallel to the first semiconductor circuit arrangement,
a first control and driver unit configured to drive the first semiconductor circuit arrangement with control signals,
wherein an additional over-voltage protection device is connected serial to the first varistor and parallel to the first semiconductor circuit arrangement, and that the additional over-voltage protection device is a gas discharge tube or a silicon thyristor for alternating current.

2. Electric switching device according to claim 1, wherein the electric switching device includes a second varistor, the second varistor is connected in parallel to the first varistor and serial to the additional over-voltage protection device.

3. Electric switching device according to claim 1, wherein the first and/or the second varistor is a metal-oxide-varistor.

4. Electric switching device according to one of the claim 1, wherein the first varistor and/or the second the second varistor has a maximum clamping voltage of 115% to 125%, preferably 120%, of the power supply voltage.

5. Electric switching device according to claim 1, wherein the gas discharge tube has a sparkover voltage of 45%-55% of the power supply voltage.

6. Electric switching device according to claim 1, wherein at the silicon thyristor for alternating current has a blocking voltage of 45%-55% of the power supply voltage.

7. Electric switching device according to claim 1, wherein the first semiconductor circuit arrangement has a collector-to-emitter voltage or a drain-to-source voltage of 190%-260%, preferably 210%-250%, of the power supply voltage.

8. Electric switching device according to claim 1, wherein a mechanical bypass switch is arranged in the first conductor path, the mechanical bypass switch is connected in parallel to the first semiconductor circuit arrangement, the first varistor, and the additional over-voltage protection device

9. Electric switching device according to claim 1. wherein the electric switching device includes a first galvanic separation switch, the first galvanic separation switch is arranged in the first conductor path, and/or that the electric switching device includes a second galvanic separation switch, the second galvanic separation switch is arranged in the second conductor path.
